(19) United States
(12) Patent Application Publication
(10) Pub. No.: US 2026/0123302 A1
(43) Pub. Date: Apr. 30, 2026

(54) METHOD AND APPARATUS FOR DEPOSITING A CARBON-CONTAINING MATERIAL

(71) Applicant: ASM IP Holding B.V., Almere (NL)

(72) Inventors: René Henricus Jozef Vervuurt, Leuven (BE); Ranjit Rohidas Borude, Leuven (BE); Timothee Blanquart, Tokyo (JP); Imane Abdellaoui, Phoenix, AZ (US); Patricio Eduardo Romero, Boutersem (BE); Alina Talmantaite, Leuven (BE); Viljami Pore, Helsinki (FI)

(21) Appl. No.: 19/369,508

(22) Filed: Oct. 27, 2025

Related U.S. Application Data
(60) Provisional application No. 63/713,622, filed on Oct. 30, 2024.

(51) Int. Cl. H01L 21/02; C23C 16/04; C23C 16/36; C23C 16/455; C23C 16/56; H01J 37/32

(52) U.S. Cl. CPC H10P 14/6339; C23C 16/045; C23C 16/36; C23C 16/45536; C23C 16/45544; C23C 16/45553; C23C 16/56; H01J 37/32449; H01J 37/32724; H10P 14/6682; H10P 14/6905; H01J 2237/332

(57) ABSTRACT

Methods for filling a gap on a substrate with a carbon-containing material are disclosed. Exemplary method includes providing a substrate comprising a gap into a reaction chamber and executing a plurality of deposition cycles. Each deposition cycle comprises providing a first precursor into the reaction chamber in vapor phase and providing a reactive species into the reaction chamber, wherein the first precursor comprises carbon.

### CROSS-REFERENCE TO RELATED APPLICATIONS

This application claims priority to and the benefit of U.S. Provisional Application No. 63/713,622, filed Oct. 30, 2024, the entirety of which is incorporated by reference herein.

### FIELD OF INVENTION

The present disclosure generally relates to the field of semiconductor processing methods and systems, and to the field integrated circuit manufacture. In particular, methods and systems suitable for forming layers comprising carbon are disclosed.

### BACKGROUND OF THE DISCLOSURE

The scaling of semiconductor devices, such as, for example, logic devices and memory devices, has led to significant improvements in the speed and density of integrated circuits. However, conventional device scaling techniques face significant challenges for future technology nodes.

For example, one challenge has been finding suitable ways of filling gaps, such as recesses, trenches, vias and the like, with a material without formation of any gaps or voids.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of the disclosure below. This summary is not intended to identify key features or essential features of the claimed subject matter, nor is it intended to be used to limit the scope of the claimed subject matter.

Various embodiments of the present disclosure relate to methods of filling a gap, to structures and devices formed using such methods, and to apparatus for preforming the methods and/or for forming the structures and/or devices. The layers may be used in a variety of applications. For example, they may be used in the field of integrated circuit manufacture.

Thus described herein is a method for filling a gap on a substrate with a carbon-containing material. The method comprises providing a substrate comprising a gap into a reaction chamber and executing a plurality of deposition cycles. Each deposition cycle comprises providing a first precursor into the reaction chamber in vapor phase and providing a reactive species into the reaction chamber. The first precursor comprises carbon.

In some embodiments, the method further comprises a step wherein, during each deposition cycle, a second precursor is provided into the reaction chamber in a vapor phase.

In some embodiments, the reactive species is generated by a plasma from a reactant gas.

In some embodiments, the reactive species comprises at least one member selected from the group consisting of argon, argon atoms, argon plasma and argon radicals.

In some embodiments, the reactive species are generated directly above the substrate.

In some embodiments, the reactive species are generated away from the substrate. In some embodiments, a remote plasma generator is used for generating the reactive species.

In some embodiments, the method further comprises an anneal step. In some embodiments, the anneal step comprises UV anneal or thermal anneal.

In some embodiments, the carbon-containing material comprises silicon carbonitride.

In some embodiments, the carbon-containing material comprises carbonitride.

In some embodiments, the first precursor is selected from the group consisting of tris(dimethylamino)silane (3DMAS), tetrakis(dimethylamino)silane (4DMAS), bis(dimethylamino)methylsilane (BDMAS), pyridine, trisilane, N′-[(disilylamino)silyl]-N,N-disilylsilanediamine, bis(dimethylamino)dimethylsilane, silanediamine, 1-trimethylsilyl-1,2,4-triazole and N,N′-disilylsilanediamine.

In some embodiments, the second precursor comprises a heterocyclic amine. In some embodiments, one or more carbon atoms in the heterocyclic amine are bonded to a methyl group or an amino group. In some embodiments, the heterocyclic amine comprises one or more amine groups. In some embodiments, the heterocyclic amine comprises an oxygen atom. In some embodiments, the heterocyclic amine has a bicyclic structure.

In some embodiments, a silicon-containing layer is formed on a three dimensional structure.

In some embodiments, the reactive species is fed into the reactor continuously.

In some embodiments, the first precursor and second precursor are fed into the reactor continuously.

In some embodiments, one of the precursors is fed into the reactor continuously and one of the precursors is fed into the reactor in pulses. In some embodiments, one of the first precursor or the second precursor is fed into the reactor continuously and the other of the first precursor or the second precursor is fed into the reactor in pulses.

In another aspect of the invention, a semiconductor processing apparatus is described. The apparatus comprises a reaction chamber comprising a substrate support for supporting a substrate; a heater constructed and arranged to heat the substrate in the reaction chamber; a plasma module comprising a radio frequency power source constructed and arranged to generate a plasma; a plasma gas source in fluid communication with the plasma module; a first precursor source in fluid connection with the reaction chamber via one or more precursor valves; and a controller configured for causing the semiconductor processing apparatus to perform a method according to the description herein.

In some embodiments, the apparatus further comprises a second precursor source in fluid connection with the reaction chamber via one or more precursor valves.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates an embodiment of a method as disclosed herein.

FIG. 2 illustrates an embodiment of a method as disclosed herein.

FIG. 3A-3C illustrates the pulsing schemes of in accordance with embodiments of a method as described herein.

FIG. 4 shows another embodiment of a system as described herein in a stylized way.

FIG. 5 shows a stylized representation of a substrate comprising a gap.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride, or silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas.

As used herein, a “precursor” includes a gas or a material that can become gaseous and that can be represented by a chemical formula that includes an element that may be incorporated during a deposition process as described herein.

The term “reactant” can refer to a gas or a material that can become gaseous and that can react with a precursor.

In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “film” or “layer” can refer to any continuous or non-continuous structure and material, such as material deposited by the methods disclosed herein. For example, a film or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate/and/or embedded in a device manufactured on that substrate. A film or layer may comprise material or a layer with pinholes and/or isolated islands. A film or layer may be at least partially continuous. A film or layer may be patterned, e.g., subdivided, and may be comprised in a plurality of semiconductor devices.

As used herein, a “structure” can be or can include a substrate as described herein. Structures can include one or more layers overlying the substrate, such as one or more layers formed according to a method as described herein. Device portions can be or include structures.

The term “deposition process” as used herein can refer to the introduction of precursors (and/or reactants) into a reaction chamber to deposit a layer over a substrate. “Cyclical deposition processes” are examples of “deposition processes”.

A method as described herein can comprise depositing a layer by a cyclic deposition process. The term “cyclic deposition process” or “cyclical deposition process” can refer to a sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a CVD component.

In some embodiments, a cyclical CVD process may comprise the introduction of two or more precursors or reactants into the reaction chamber, wherein there may be a time period of overlap between the two or more precursors or reactants in the reaction chamber resulting in both an ALD component of the deposition and a CVD component of the deposition. This is referred to as a hybrid process. In accordance with further embodiments, a cyclical deposition process may comprise a continuous flow of one reactant or precursor into the reaction chamber and periodic pulsing of a second reactant or precursor into the reaction chamber.

A method as described herein can comprise depositing a layer an atomic layer deposition process. The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g., using a noble gas, may be provided between a precursor pulse and a reactant pulse, thus avoiding or at least minimizing gas phase interactions between the precursor and the reactant. It shall be understood that a purge can be effected either in time or in space, or both. For example, in the case of temporal purges, a purge step can be used, e.g., in the temporal sequence of providing a first precursor to a reaction chamber, providing a purge gas to the reaction chamber, and providing a second precursor to the reaction chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

Further, in this disclosure, any two numbers of a variable can constitute a workable range of the variable, and any ranges indicated may include or exclude the endpoints. Additionally, any values of variables indicated may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments.

The term “copolymerization” can refer to the process where two or more different polymers are combined in a molecular chain. The composition of the molecular chain, i.e., the ratio of the different polymers in the chain, can be controlled by changing the monomer ratio in the process. In accordance with the current disclosure, if all monomers yield a flowable film, flowability is also expected for the copolymer.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Z₀, the phrase is intended to refer to a single element selected from X, Y, and Z, a combination of elements selected from the same class (e.g., X₁ and X₂) as well as a combination of elements selected from two or more classes (e.g., Y₁ and Z₀).

Silicon carbonitride (SiCN) can refer to a material that includes silicon, carbon and nitrogen. In some embodiments, the material for filling the gap according to the current disclosure comprises silicon carbonitride. As used herein, unless otherwise stated, SiCN is not intended to limit, restrict, or define the bonding or chemical state, for example, the oxidation state of any Si, C, N, and/or any other elements in the film. In some embodiments, SiCN may comprise one or more elements in addition to Si, C, and N, such as O and H. In some embodiments, the SiCN may comprise Si—H bonds in addition to Si—C and/or Si—O bonds. In some embodiments, the SiCN may comprise from greater than 0% to about 60% carbon on an atomic basis (i.e., atomic-percent basis). In some embodiments, the SiCN may comprise from about 0.1% to about 40%, from about 0.5% to about 30%, from about 1% to about 30%, or from about 5% to about 20% carbon on an atomic basis. In some embodiments, the SiCN may comprise from greater than 0% to about 70% nitrogen on an atomic basis. In some embodiments, the SiCN may comprise from about 10% to about 70%, from about 15% to about 50%, or from about 20% to about 40% nitrogen on an atomic basis. In some embodiments, the SiCN may comprise greater than 0% to about 50% silicon on an atomic basis. In some embodiments, the SiOC may comprise from about 10% to about 50%, from about 15% to about 40%, or from about 20% to about 35% silicon on an atomic basis. In some embodiments, the SiCN may comprise from about 0.1% to about 40%, from about 0.5% to about 30%, from about 1% to about 30%, or from about 5% to about 20% hydrogen on an atomic basis. In some embodiments, the SiCN may not comprise oxygen. In some embodiments, the SiCN includes at least one Si—C bond and/or at least one Si—N bond from a precursor, discussed in more detail below.

Carbonitride (CN) can refer to a material that includes carbon and nitrogen. In some embodiments, the material for filling the gap according to the current disclosure comprises a carbonitride. As used herein, unless otherwise stated, the CN is not intended to limit, restrict, or define the bonding or chemical state, for example, the oxidation state of any C, N, and/or any other elements in the film. In some embodiments, the CN may comprise one or more elements in addition to C, and N, such as O and H. In some embodiments, the CN may comprise C—H bonds in addition to C—N and/or C—C bonds. In some embodiments, the CN may comprise from greater than 0% to about 99% carbon on an atomic basis. In some embodiments, the CN may comprise from about 0.1% to about 90%, from about 0.5% to about 80%, from about 1% to about 70%, or from about 5% to about 60% carbon on an atomic basis. In some embodiments, the CN may comprise from greater than 0% to about 70% nitrogen on an atomic basis. In some embodiments, the CN may comprise from about 10% to about 70%, from about 15% to about 50%, or from about 20% to about 40% nitrogen on an atomic basis. In some embodiments, the CN may comprise from about 0.1% to about 40%, from about 0.5% to about 30%, from about 1% to about 30%, or from about 5% to about 20% hydrogen on an atomic basis. In some embodiments, the CN may not comprise oxygen. In some embodiments, the CN includes at least one C—C bond and/or at least one C—N bond from a precursor, discussed in more detail below.

As used herein, the term “overlap” can mean coinciding with respect to time and within a reaction chamber. For example, with regard to gas pulse periods, such as precursor pulse periods and reactant periods, two or more gas periods can overlap when gases from the respective pulse periods are within the reaction chamber or provided to the reaction chamber for a period of time. Similarly, a plasma power period can overlap with a gas (e.g., reactant gas) period (which can be continuous through one or more cycles, described below).

Described herein is a method of filling a gap. The method comprises providing a substrate that comprises a gap to a reaction chamber. A monocrystalline silicon wafer may be a suitable substrate. Other substrates may be suitable as well, e.g., monocrystalline germanium wafers, gallium arsenide wafers, quartz, sapphire, glass, steel, aluminum, silicon-on-insulator substrates, plastics, etc.

The method further comprises executing a plurality of deposition cycles. Each deposition cycle comprises providing a first precursor into the reaction chamber in vapor phase; and providing a reactive species into the reaction chamber plasma. The first precursor comprises carbon. Accordingly, at least part of the gap is filled with a carbon-containing material.

In some embodiments, the method further comprises providing a second precursor into the reaction chamber in vapor phase during each deposition cycle.

In some embodiments, the vapor phase first and second precursors comprise oligomers which fill the gap in the substrate and oligomerize, due to reaction with the reactive species. The oligomerization results in the precursors transferring into a fluid, which can fill the gap in the substrate. The fluid then solidifies as the oligomers undergo chain growth, in other words crosslinking, and result in a solid material. In this way, the gaps can be filled even at temperatures that are lower than the bulk melting point of the solid material that is formed by a method as disclosed herein. Still, the presently described methods can also be used at conversion temperatures which exceed the melting point of the solid material filling the gap formed by a method as described herein. In such cases, the fluid can, in some embodiments, be solidified by cooling the substrate.

In some embodiments, the carbon-containing material is formed on a three dimensional structure. In some embodiments, the three dimensional structure may comprise gaps. Exemplary gaps include recesses, contact holes, vias, trenches, and the like. In some embodiments, the gap has a depth of at least 5 nm to at most 500 nm, or of at least 10 nm to at most 250 nm, or from at least 20 nm to at most 200 nm, or from at least 50 nm to at most 150 nm, or from at least 100 nm to at most 150 nm.

In some embodiments, the gap has a width of at least 10 nm to at most 10000 nm, or of at least 20 nm to at most 5000 nm, or from at least 40 nm to at most 2500 nm, or from at least 80 nm to at most 1000 nm, or from at least 100 nm to at most 500 nm, or from at least 150 nm to at most 400 nm, or from at least 200 nm to at most 300 nm.

In some embodiments, the gap has a length of at least 10 nm to at most 10000 nm, or of at least 20 nm to at most 5000 nm, or from at least 40 nm to at most 2500 nm, or from at least 80 nm to at most 1000 nm, or from at least 100 nm to at most 500 nm, or from at least 150 nm to at most 400 nm, or from at least 200 nm to at most 300 nm. In some embodiments, an aspect ratio of the gaps can range from, for example, about 5:1 to about 30:1.

In some embodiments, the substrate is maintained at a temperature of at least −25° C. to at most 400° C., or at a temperature of at least 0° C. to at most 200° C., or at a temperature of at least 25° C. to at most 150° C., or at a temperature of at least 50° C. to at most 100° C. while exposing the substrate to the reactive species.

In some embodiments, the first and/or second precursor is provided into the reaction chamber at a substrate temperature of less than 800° C., or of at least 50° C. to at most 500° C., or of at least 100° C. to at most 300° C., or at least 50° C. to at most 75° C. In some embodiments, the first and/or second precursor is provided into the reaction chamber at a temperature of at least −25° C. to at most 300° C., or at a temperature of at least 0° C. to at most 250° C., or at a temperature of at least 25° C. to at most 200° C., or at a temperature of at least 50° C. to at most 150° C., or at a temperature of at least 75° C. to at most 125° C.

In some embodiments, the presently described methods are carried out at a pressure of less than 760 Torr or of at least 0.2 Torr to at most 760 Torr, of at least 1 Torr to at most 100 Torr, or of at least 1 Torr to at most 10 Torr, or of at least 10 Torr to at most 55 Torr. In some embodiments, the convertible layer is deposited at a pressure of at mot 10.0 Torr, or at a pressure of at most 5.0 Torr, or at a pressure of at most 3.0 Torr, or at a pressure of at most 2.0 Torr, or at a pressure of at most 1.0 Torr, or at a pressure of at most 0.1 Torr, or at a pressure of at most 10⁻² Torr, or at a pressure of at most 10⁻³ Torr, or at a pressure of at most 10⁻⁴ Torr, or at a pressure of at most 10⁻⁵ Torr, or at a pressure of at least 0.1 Torr to at most 10 Torr, or at a pressure of at least 0.2 Torr to at most 5 Torr, or at a pressure of at least 0.5 Torr to at most 2.0 Torr.

In some embodiments, the method further comprises a step of curing the material deposited into the gap. In some embodiments, the curing can be performed after the gap is entirely filled. Alternatively, curing can be done cyclically. For example, a method as described herein can comprise a curing step after each step of providing a reactive species into the reaction chamber. Alternatively, a method as described herein can comprise a curing step after from at least 1% to at most 2%, or from at least 2% to at most 5%, or from at least 5% to at most 10%, or from at least 10% to at most 20%, or from at least 20% to at most 50%, or from at least 50% to at most 100 of the steps of providing a reactive species into the reaction chamber.

In some embodiments, the methods described herein may further include an anneal step. An anneal step suitably comprises subjecting the substrate to a form of energy, e.g., at least one of heat energy, radiation, and particles. Exemplary anneal steps comprise exposing the substrate to UV radiation. Additionally or alternatively, an anneal step can comprise exposing the substrate to a direct plasma, e.g. a noble gas plasma, such as an argon plasma. Additionally or alternatively, an anneal step can comprise exposing the substrate to one or more reactive species such as ions and/or radicals generated in a remote plasma, e.g. a remote noble gas plasma, such as a remote argon plasma. Additionally or alternatively, an anneal step can comprise exposing the substrate to photons, e.g. at least one of UV photons, photons in the visible spectrum, IR photons, or photons in the microwave spectrum. Additionally or alternatively, an anneal step can comprise heating the substrate, e.g. thermal anneal. In some embodiments, the substrate is heated to a temperature of about 200-300° C., such as about 250° C. In some embodiments, the anneal time is between 1000 seconds and 2000 seconds. During the anneal step, the crosslinked solidified material becomes reflowable. In other words, the anneal affects the crosslinking of the polymer so that the material behaves like a fluid again. This reflowable form can be beneficial to fill in all possible voids or seams that might still take place in the gap fill material to form a fully seam-free and void-free gap fill.

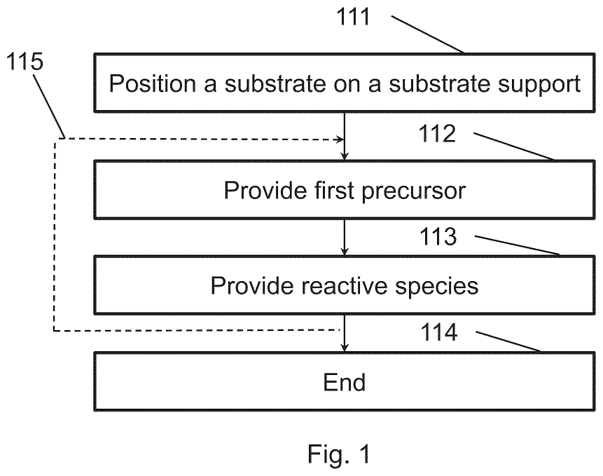

Now turning to the figures, FIG. 1 shows a schematic representation of an embodiment of a method as described herein. The method can used to fill a gap, for example, in order to form an electrode in a semiconductor device. However, the presently described methods are not limited to such applications. The method for filling a gap can be a cyclic depositing process, such as ALD process, or CVD process, or PEALD process, or PECVD process. The method comprises a step 111 of positioning a substrate on a substrate support. The substrate support is positioned in a reaction chamber. Suitable substrate supports include pedestals, susceptors, and the like.

During step 111, the substrate can be brought to a desired temperature for subsequent processing using, for example, a substrate heater and/or radiative or other heaters. Suitable pressures and temperatures are as described above.

The method further comprises step 112 of providing a first precursor into the reaction chamber in vapor phase. In some embodiments, the first precursor may be selected from the group consisting of tris(dimethylamino)silane (3DMAS), tetrakis(dimethylamino)silane (4DMAS), bis(dimethylamino)methylsilane (BDMAS), pyridine, trisilane, N′-[(disilylamino)silyl]-N,N-disilylsilanediamine, bis(dimethylamino)dimethylsilane, silanediamine, 1-trimethylsilyl-1,2,4-triazole and N,N′-disilylsilanediamine. A flowrate of the first precursor to reaction chamber can be controlled and be about 10 to about 2000 sccm. Optionally, the reaction chamber is purged after step 112.

Then, the method further comprises step 113 of providing a reactive species into the reaction chamber in vapor phase. In some embodiments, the reactive species comprises at least one member selected from the group consisting of argon, argon atoms, argon plasma and argon radicals. In some embodiments, the reactive species may comprise nitrogen, nitrogen atoms, nitrogen plasma or nitrogen radicals. In some embodiments, the reactive species comprises a mixture of argon and nitrogen. The reactive species is generated by a plasma from a reactant gas. The plasma is formed by providing plasma power to an electrode (e.g., within the reactor).

A plasma power used during the method can be between 30 and 800 W, for example, between 100 and 500 W. A frequency of the plasma power can be between about 10,000 and 100,000 Hz or about 5,000 and 200,000 Hz. In some embodiments, the reactive species are generated directly above the substrate. In some embodiments, the reactive species are generated away from the substrate. In some embodiments, a remote plasma generator is used for generating the reactive species. Optionally, the reaction chamber is then purged.

Optionally, the step of providing the first precursor 112 and the step of providing the reactive species 113 are repeated 115 one or more times. When a sufficient amount of material has been formed in the gap, the method ends 114. The total number of cycles comprised in a method as described herein depends, inter alia, on the total layer thickness that is desired. In some embodiments, the method comprises from at least 1 cycle to at most 100 cycles, or from at least 2 cycles to at most 80 cycles, or from at least 3 cycles to at most 70 cycles, or from at least 4 cycles to at most 60 cycles, or from at least 5 cycles to at most 50 cycles, or from at least 10 cycles to at most 40 cycles, or from at least 20 cycles to at most 30 cycles. In some embodiments, the method comprises at most 100 cycles, or at most 90 cycles, or at most 80 cycles, or at most 70 cycles, or at most 60 cycles, or at most 50 cycles, or at most 40 cycles, or at most 30 cycles, or at most 20 cycles, or at most 10 cycles, or at most 5 cycles, or at most 4 cycles, or at most 3 cycles, or at most 2 cycles, or a single cycle.

It is to be noted that the steps of providing a first precursor into the reaction chamber 112 and providing a reactive species into the reaction chamber 113 can be performed in which ever order or simultaneously. In other words, step 112 can be performed first after which step 113 is performed, or step 113 can be performed first after which step 112 is performed, or steps 112 and 113 can be performed at the same time so that both the first precursor and the reactive species are provided into the reaction chamber at the same time or at least in a partially overlapping manner.

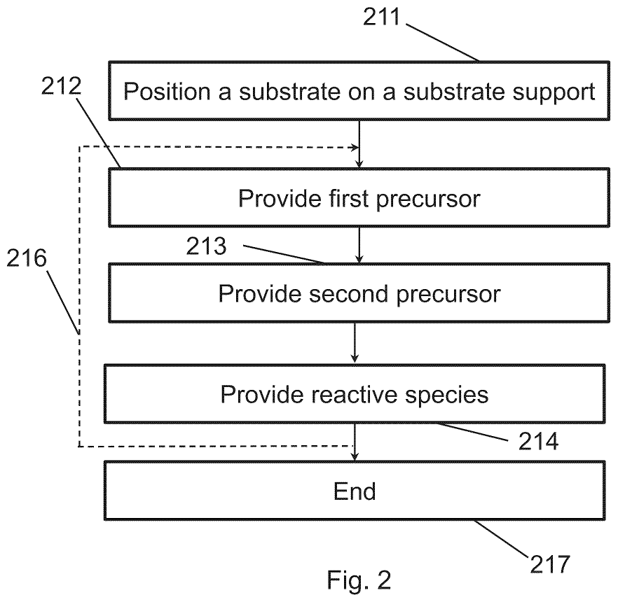

FIG. 2 shows a schematic representation of another embodiment of a method as described herein. The method can be suitable for filling a gap with a material. As illustrated, the method includes the steps of positioning a substrate on a substrate support 211, providing a first precursor into a reaction chamber in vapor phase 212, providing a second precursor into a reaction chamber in vapor phase 213, providing a reactive species into the reaction chamber 214, and ending the process 217. As illustrated, steps 212, 213 and 214 can be repeated a number of times as illustrated by loop 216.

During step 211, a substrate is positioned on a substrate support. Step 211 can be the same or similar to step 111 above.

During step 212, a first precursor is provided into the reaction chamber in vapor phase. Step 212 can be the same or similar to step 112 above.

During step 213, a second precursor is provided into the reaction chamber in vapor phase. In some embodiments, the second precursor may comprise a heterocyclic amine. In some embodiments, one or more carbon atoms in the heterocyclic amine are bonded to a methyl group or an amino group. In some embodiments, the heterocyclic amine comprises one or more amine groups. In some embodiments, the heterocyclic amine comprises an oxygen atom. In some embodiments, the heterocyclic amine has a bicyclic structure.

In some embodiments, the heterocyclic amine has a general structure according to Formula i)

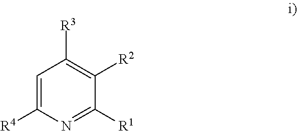

wherein, in some embodiments, R¹, R², R³ and R⁴ are hydrogen atoms. In some embodiments, R¹ is a methyl group and R², R³ and R⁴ are hydrogen atoms. In some embodiments, R¹ is an amino group and R², R³ and R⁴ are hydrogen atoms. In some embodiments, R¹ is an amino group, R² and R⁴ are hydrogen and R³ is a methyl group.

In some embodiments, the heterocyclic amine has a general structure according to Formula ii)

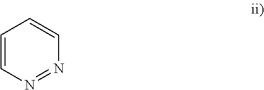

In some embodiments, the heterocyclic amine has a general structure according to Formula iii)

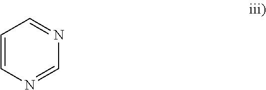

In some embodiments, the heterocyclic amine has a general structure according to Formula iv)

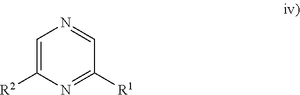

wherein, in some embodiments, R¹ and R² are hydrogen. In some embodiments, R¹ is an amino group and R² is hydrogen. In some embodiments, R¹ is a methyl group and R² is hydrogen.

In some embodiments, the heterocyclic amine has a general structure according to Formula v)

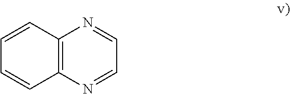

In some embodiments, the heterocyclic amine has a general structure according to Formula vi)

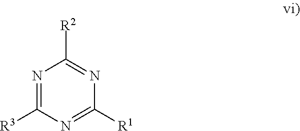

wherein, in some embodiments, R¹, R² and R³ are hydrogen. In some embodiments, R¹ is a methyl group and R² and R³ are hydrogen. In some embodiments, R¹, R² and R³ are methyl groups.

In some embodiments, the heterocyclic amine has a general structure according to Formula vii)

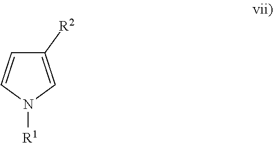

wherein, in some embodiments, R¹ and R² are hydrogen. In some embodiments, R¹ is a methyl group and R² is hydrogen. In some embodiments, R¹ is hydrogen and R² is a methyl group.

In some embodiments, the heterocyclic amine has a general structure according to Formula viii)

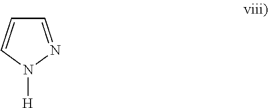

In some embodiments, the heterocyclic amine has a general structure according to Formula ix)

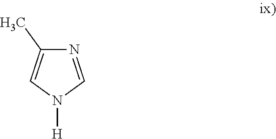

In some embodiments, the heterocyclic amine has a general structure according to Formula x)

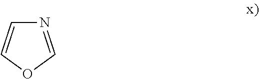

A flowrate of the second precursor to reaction chamber can be controlled and be about 10 to about 2000 sccm. Optionally, the reaction chamber is purged after step 212.

During step 214, a reactive species is provided into the reaction chamber. Step 214 can be the same or similar to step 113 above.

Optionally, the step of providing the first precursor 212, the step of providing the second precursor 213 and the step of providing the reactive species 214 are repeated 216 one or more times. When a sufficient amount of material has been formed in the gap, the method ends 217. The total number of cycles comprised in a method as described herein depends, inter alia, on the total layer thickness that is desired. In some embodiments, the method comprises from at least 1 cycle to at most 100 cycles, or from at least 2 cycles to at most 80 cycles, or from at least 3 cycles to at most 70 cycles, or from at least 4 cycles to at most 60 cycles, or from at least 5 cycles to at most 50 cycles, or from at least 10 cycles to at most 40 cycles, or from at least 20 cycles to at most 30 cycles. In some embodiments, the method comprises at most 100 cycles, or at most 90 cycles, or at most 80 cycles, or at most 70 cycles, or at most 60 cycles, or at most 50 cycles, or at most 40 cycles, or at most 30 cycles, or at most 20 cycles, or at most 10 cycles, or at most 5 cycles, or at most 4 cycles, or at most 3 cycles, or at most 2 cycles, or a single cycle.

It is to be noted that the steps of providing a first precursor into the reaction chamber 212, providing a second precursor into the reaction chamber 213 and providing a reactive species into the reaction chamber 214 can be performed in any order or simultaneously. For example, step 212 can be performed first after which step 213 is performed after which step 214 is performed, or steps 212, 213 and 214 can be performed at the same time so that both the first precursor and the reactive species are provided into the reaction chamber at the same time, or at least in a partially overlapping manner.

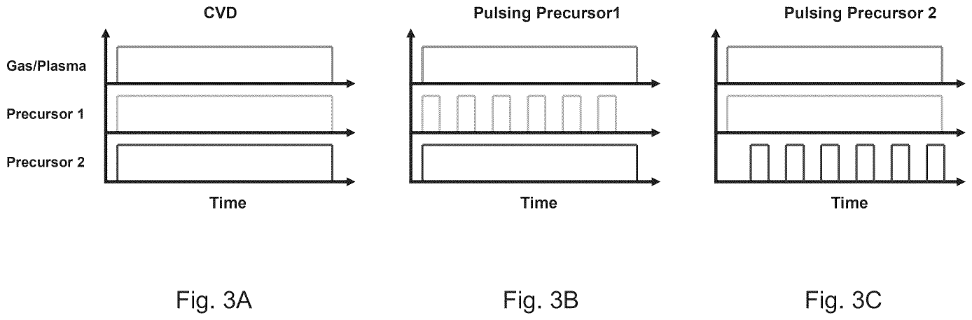

Now turning to FIGS. 3A-3C, FIGS. 3A-3C illustrate the pulsing schemes in accordance with embodiments of a method as described herein. In particular, FIGS. 3A-3C illustrate on/off sequences for gas flow and for plasma power or for provisions of active species.

As illustrated, a sequence comprises a reactant gas/plasma power pulse, a first precursor pulse and a second precursor pulse. The pulses may be the same or similar to steps 212-214 as illustrated above in accordance with FIG. 2. The reactant gas and plasma power pulse provide a reactive species into the reaction chamber.

In the embodiment of FIG. 3A, a reactant gas/plasma power pulse, a first precursor pulse, and a second precursor pulse are all simultaneously and continuously provided into the reaction chamber. Having all the elements reaching the reaction chamber continuously and simultaneously, the process can be described as a chemical vapor deposition process (CVD). Having the plasma on, the process can be described as a plasma-enhanced CVD (PECVD) process. In this process, the process gasses react in the reaction space of the reaction chamber and form the copolymers as described above to fill the gap on the substrate.

FIG. 3B illustrates an embodiment where a reactant gas/plasma power pulse is provided continuously into the reaction chamber, the first precursor is provided in a pulsed manner into the reaction chamber, and the second precursor is provided continuously into the reaction chamber. Pulsing the first precursor offers an increased control of the composition of the formed material. The pulsing time of the first precursor can be between 10 and 50% of the pulse time of the continuous feed of the second precursor.

FIG. 3C illustrates an embodiment where a reactant gas/plasma pulse is provided continuously into the reaction chamber, the first precursor is provided continuously into the reaction chamber, and the second precursor is provided in a pulsed manner into the reaction chamber. Pulsing the second precursor offers an increased control of the composition of the formed material. The pulsing time of the second precursor can be between 10 and 50% of the pulse time of the continuous feed of the first precursor.

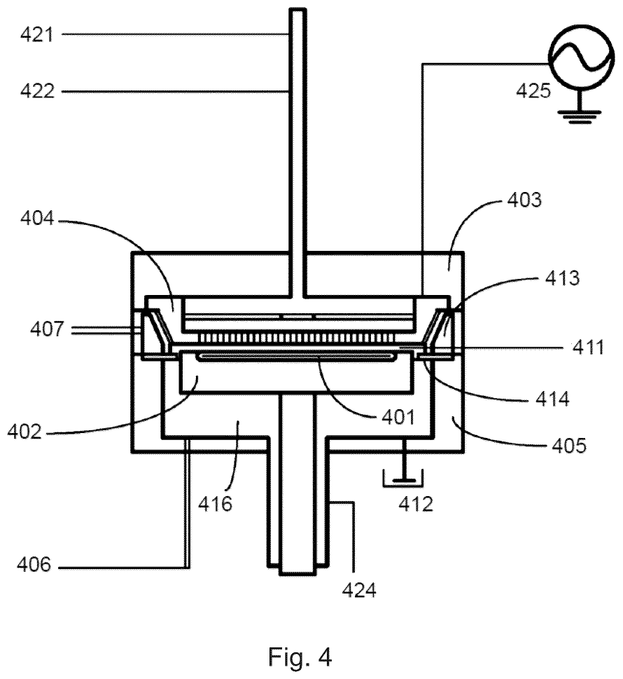

The presently provided methods may be executed in any suitable apparatus, including in an embodiment of a semiconductor processing system as shown in FIG. 4. FIG. 4 is a schematic view of a plasma-enhanced atomic layer deposition (PEALD) apparatus or plasma-enhanced chemical vapor deposition (PECVD) apparatus, usable in some embodiments of the present invention. In this figure, by providing a pair of electrically conductive flat-plate electrodes (402,404) in parallel and facing each other in the interior (411) (reaction zone) of a reaction chamber (403), applying RF power (e.g. at 13.56 MHz and/or 27 MHz and/or 12.9 MHz and/or 430 kHz) from a power source (425) to one side, and electrically grounding the other side (412), a plasma can be generated between the electrodes. In some embodiments, there is no need for the semiconductor processing apparatus to generate a plasma during the steps when a precursor is provided to the reaction chamber, or during optional purges between subsequent processing steps, and no RF power need be applied to any one of the electrodes during those steps or purges. A temperature regulator may be provided in a lower stage (402), i.e., the lower electrode. A substrate (401) is placed thereon and its temperature is kept constant at a given temperature. The upper electrode (404) can serve as a shower plate as well, and various gasses such as a plasma gas, a reactant gas and/or a dilution gas, if any, as well as a precursor gas can be introduced into the reaction chamber (403) through a gas line (421) and a gas line (422), respectively, and through the shower plate (404). Additionally, in the reaction chamber (403), a circular duct (413) with an exhaust line (417) is provided, through which the gas in the interior (411) of the reaction chamber (403) is exhausted. Additionally, a transfer chamber (405) is disposed below the reaction chamber (403) and is provided with a gas seal line (424) to introduce seal gas into the interior (411) of the reaction chamber (403) via the interior (416) of the transfer chamber (405), wherein a separation plate (414) for separating the reaction zone and the transfer zone is provided.

Note, a gate valve through which a wafer may be transferred into or from the transfer chamber (405) is not shown this Figure, but may be present. The transfer chamber is also provided with an exhaust line (406).

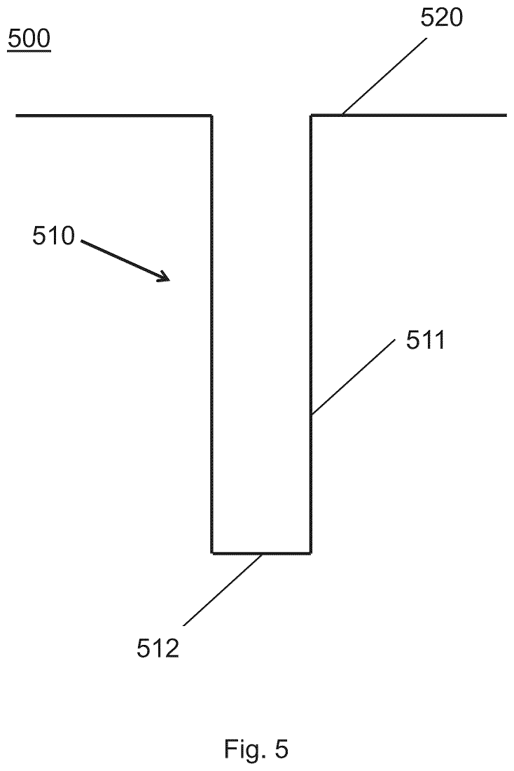

FIG. 5 shows a schematic representation of a substrate (500) comprising a gap (510). The gap (510) comprises a sidewall (511) and a distal end (512). The substrate further comprises a proximal surface (520). In some embodiments, the sidewall (511) and the distal end (512) comprise the same material. In some embodiments, at least one of the sidewall (511) and the distal end (512) comprise a dielectric material, such as a silicon containing dielectric, such as silicon oxide, silicon nitride, silicon carbide, and mixtures thereof. In some embodiments, at least one of the sidewall (511) and the distal end (512) comprise a metal, such as a transition metal, a post transition metal, or a rare earth metal. In some embodiments, the metal comprises Cu, Co, W, Ru, Mo, Al, or an alloy thereof. In some embodiments, at least one of the sidewall (511) and the distal end (512)

In some embodiments, the sidewall (511) and the distal end (512) have an identical, or a substantially identical, composition. In some embodiments, the sidewall (511) and the distal end (512) have a different composition. In some embodiments, the sidewall and the distal end (512) comprise a dielectric material. In some embodiments, the sidewall (511) and the distal end (512) comprise a metal. In some embodiments, the sidewall (611) comprises a metal and the distal end (512) comprises a dielectric material. In some embodiments, the sidewall (511) comprises a dielectric material and the distal end comprises a metal.

In some embodiments, the proximal surface (520) has the same composition as the sidewall (511). In some embodiments, the proximal surface (520) has a different composition than the sidewall (511). In some embodiments, the proximal surface (520) has a different composition than the distal end (512). In some embodiments, the proximal surface (520) has the same composition as the distal end (512).

In some embodiments, the proximal surface (520), the sidewall (511), and the distal end (512) comprise the same material. In some embodiments, the proximal surface (520), the sidewall (511), and the distal end (512) comprise a dielectric material. In some embodiments, the proximal surface (520), the sidewall (511), and the distal end (512) comprise a metal. In some embodiments, the proximal surface (520), the sidewall (511), and the distal end (512) comprise a semiconductor.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for filling a gap on a substrate with a carbon-containing material, the method comprising:
providing a substrate comprising a gap into a reaction chamber; and
executing a plurality of deposition cycles, wherein each deposition cycle comprises:
providing a first precursor into the reaction chamber in vapor phase; and
providing a reactive species into the reaction chamber,
wherein the first precursor comprises carbon.

2. The method according to claim 1, further comprising, during each deposition cycle, providing a second precursor into the reaction chamber in vapor phase.

3. The method according to claim 2, wherein the first precursor and second precursor are fed into the reactor continuously.

4. The method according to claim 2, wherein one of the first or second precursors is fed into the reactor continuously and the other of the first or second precursors is fed into the reactor in pulses.

5. The method according to claim 1, wherein the reactive species is generated by a plasma from a reactant gas.

6. The method according to claim 1, wherein the reactive species comprises at least one member selected from the group consisting of argon, argon atoms, argon plasma and argon radicals.

7. The method according to claim 1, wherein the reactive species are generated directly above the substrate.

8. The method according to claim 1, wherein the reactive species are generated away from the substrate, and wherein a remote plasma generator is used for generating the reactive species.

9. The method according to claim 1, further comprising an anneal step.

10. The method according to claim 1, wherein the carbon-containing material comprises silicon carbonitride.

11. The method according to claim 1, wherein the carbon-containing material comprises carbonitride.

12. The method according to claim 1, wherein the first precursor is selected from the group consisting of tris(dimethylamino)silane (3DMAS), tetrakis(dimethylamino)silane (4DMAS), bis(dimethylamino)methylsilane (BDMAS), pyridine, trisilane, N′-[(disilylamino)silyl]-N,N-disilylsilanediamine, bis(dimethylamino)dimethylsilane, silanediamine, 1-trimethylsilyl-1,2,4-triazole and N,N′-disilylsilanediamine.

13. The method according to claim 1, further comprising, during each deposition cycle, providing a second precursor into the reaction chamber in vapor phase, and wherein the second precursor comprises a heterocyclic amine.

14. The method according to claim 13, wherein one or more carbon atoms in the heterocyclic amine are bonded to a methyl group or an amino group.

15. The method according to claim 13, wherein the heterocyclic amine comprises one or more amine groups.

16. The method according to claim 13, wherein the heterocyclic amine comprises an oxygen atom.

17. The method according to claim 13, wherein the heterocyclic amine has a bicyclic structure.

18. The method according to claim 1, wherein the reactive species is fed into the reactor continuously.

19. A semiconductor processing apparatus comprising:
a reaction chamber comprising a substrate support for supporting a substrate;
a heater constructed and arranged to heat the substrate in the reaction chamber;
a plasma module comprising a radio frequency power source constructed and arranged to generate a plasma;
a plasma gas source in fluid communication with the plasma module;
a first precursor source in fluid connection with the reaction chamber via one or more precursor valves; and
a controller configured for causing the semiconductor processing apparatus to perform a method according to claim 1.

20. The semiconductor processing apparatus of claim 19, further comprising a second precursor source in fluid connection with the reaction chamber via one or more precursor valves.
